(19) United States
(12) Patent Application Publication
(10) Pub. No.: US 2025/0197991 A1
(43) Pub. Date: Jun. 19, 2025

(54) AREA SELECTIVE DEPOSITION

(71) Applicant: ASM IP Holding B.V., Almere (NL)

(72) Inventors: Sabrina Myriam Guillemot Wack, Phoenix, AZ (US); Krzysztof Kamil Kachel, Chandler, AZ (US)

(21) Appl. No.: 18/979,794

(22) Filed: Dec. 13, 2024

Related U.S. Application Data
(60) Provisional application No. 63/611,596, filed on Dec. 18, 2023.

(51) Int. Cl. C23C 16/04; C23C 16/28; C23C 16/44; C23C 16/455

(52) U.S. Cl. CPC C23C 16/042; C23C 16/28; C23C 16/4408; C23C 16/45525

(57) ABSTRACT

A method, system and apparatus for selective deposition on a substrate, comprising providing the substrate in a reaction chamber, the substrate comprising a first surface and a second surface, wherein the first surface is materially different from the second surface, wherein the first surface is a metal oxide, metal nitride, metal oxynitride, or a metal carbide or a combination thereof, wherein the second surface is a dielectric or a metal and contacting the substrate with a precursor comprising a hydrophobic compound to selectively deposit a passivation layer on the first surface relative to the second surface.

### CROSS-REFERENCE TO RELATED APPLICATIONS

This application is a nonprovisional of, and claims priority to and the benefit of, U.S. Provisional Patent Application No. 63/611,596, filed Dec. 18, 2023 and entitled “AREA SELECTIVE DEPOSITION,” which is hereby incorporated by reference herein.

### FIELD

The present disclosure relates to deposition of organic thin films, including selective deposition on a first surface of a substrate relative to a second surface.

### DESCRIPTION OF RELATED ART

Shrinking device dimensions in semiconductor manufacturing calls for new innovative processing approaches. Conventionally, patterning in semiconductor processing involves subtractive processes, in which blanket layers are deposited, masked by photolithographic techniques, and etched through openings in the mask. Additive patterning is also known, in which masking steps precede deposition of the materials of interest, such as patterning using lift-off techniques or damascene processing. In most cases, expensive multi-step lithographic techniques are applied for patterning.

Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing. A need exists for more efficient and reliable techniques for improving selectivity and decreasing defectivity in selective deposition.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### BRIEF SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In one aspect, a process for selective deposition of a metal on a substrate, includes a) providing the substrate in a reaction chamber, the substrate includes a first surface, a second surface and a third surface, b) contacting the substrate with a first precursor comprising a first alkylaminosilane to selectively deposit a first passivation layer on the first surface, c) contacting the substrate with a second precursor comprising a hydrophobic group to selectively deposit a second passivation layer on the second surface, and d) contacting the substrate with a first inhibitor precursor comprising an amine and e) contacting the substrate with a second inhibitor precursor comprising a dianhydride to selectively deposit an inhibitor layer on the third surface.

The process may also include f) purging the reaction chamber, and performing at least one of operations b), c), d), e), or f) in any order, until the first passivation layer, the second passivation layer or the inhibitor layer, or a combination thereof, are deposited onto respective ones of the first surface, the second surface or the third surface, or a combination thereof.

The process may also include repeating the performing the at least one of operations b), c), d), e), or f) in any order, until at least one of the first passivation layer reaches a first predetermined thickness, the second passivation layer reaches a second predetermined thickness or the inhibitor layer reaches a third predetermined thickness, or a combination thereof.

The process may also include where the first passivation layer has a fourth surface and is deposited relative to the second surface and the third surface, the second passivation layer has a fifth surface and is deposited relative to the third surface and the fourth surface, and the inhibitor layer has a sixth surface and is deposited relative to the fourth surface and the fifth surface.

The process may also include where the first surface includes a dielectric surface. The process may also include where the dielectric surface is a low-k material.

The process may also include where the second surface includes a metal oxide, metal nitride, metal oxynitride, or a metal carbide or a combination thereof. The process may also include where the second surface includes AlOx, CoOx, CrOx, GaOx, HfOx, MnOx, MoOx, NbOx, NiOx, RuOx, TaOx, TiOx, WOx, ZnOx, TiN, TaN, MON, AlN, WN, TaON, SiCOx, SiOx, SiO₂, SiC, SiOC, SION, SIOCN, SiGe, SiN or ZrOx, or any combination thereof.

The process may also include where the third surface includes a metal. The process may also include where the metal includes aluminum (Al), chromium (Cr), cobalt (Co), copper (Cu), gallium (Ga), indium (In), iron (Fe), manganese (Mn), molybdenum (Mo), nickel (Ni), niobium (Nb), ruthenium (Ru), tantalum (Ta), titanium (Ti), tungsten (W), vanadium (V), or zinc (Zn), or a combination thereof.

The process may also include where the first alkylaminosilane is allyltrimethylsilane (TMS-A), chlorotrimethylsilane (TMS-Cl), N-(trimethylsilyl) imidazole (TMS-Im), octadecyltrichlorosilane (ODTCS), hexamethyldisilazane (HMDS), N-(trimethylsilyl) dimethylamine (TMSDMA), trimethylchlorosilane, or 1,1,1-Trimethoxy-N,N-dimethylsilanamine or a combination thereof.

The process may also include where the second precursor includes tridecafluoro-1,1,2,2-tetrahydrooctylmethyl-bis(dimethylamino)silane.

The process may also include where the dianhydride is pyromellitic dianhydride (PMDA) or pyromellitic dithioanhydride (PMDTA). The process may also include where the amine is a diamine, a triamine, a tetraamine, or a cyclic compound includes at least two primary amines, or a combination thereof.

The process may also include where the second precursor includes a second alkylaminosilane includes a hydrophobic group that is partially halogenated or fully halogenated with one or more of fluorine, chlorine, bromine, or iodine. The process may also include where the second precursor includes a second alkylaminosilane includes a structure represented by general formula (1):

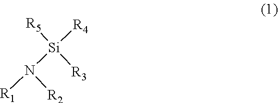

where R1 and R2 each independently comprise an H or an alkyl group, where R3 and R4 each independently comprise an H, an alkyl or an amino group of the formula NR1R2, where any two or more of R1, R2, R3, and R4 can comprise a same alkyl group, and where R5 is a hydrophobic halocarbon.

The process may also include where the hydrophobic halocarbon is a carbon chain includes one or more of CH2, CHX and CX2 units; where X is independently selected from fluorine, chlorine, bromine, or iodine. The process may also include where the hydrophobic halocarbon is non-chlorinated. The process may also include where the hydrophobic halocarbon is a fluorocarbon chain includes CH2, CHF or CF2 units, or a combination thereof. The process may also include where R5 includes a C1-C100 chain includes, units independently selected from: unhalogenated C, CX, CX2, or CX3, where X is independently selected from fluorine, chlorine, bromine, or iodine. The process may also include where the second alkylaminosilane includes dialkylaminosilane and the hydrophobic halocarbon includes 1-100 carbon atoms. The process may also include where R1, R2, R3 and R4 each independently comprise an alkyl selected from the group consisting of: methyl, ethyl, n-propyl, isopropyl, n-butyl, i-butyl, t-butyl, or s-butyl. The process may also include where the removal agent is H2 plasma or O3. The process may also include where R5 includes an alkyl or an aryl group, or a combination thereof.

The process may also include exposing the substrate to a removal agent, and removing the first passivation layer, the second passivation layer and a portion of the inhibitor layer responsive to exposure to the removal agent. The process may also include subsequent to the removing, depositing a film over the first surface, the second surface, or a portion of the third surface, or a combination thereof. The process may also include where the film includes a metal, a metal nitride, a metal carbide, a silicon oxynitride or a silicon oxycarbide, or any combination thereof. The process may also include where the film includes Al, Cu, W, Co, Nb, Mo, Ru, Ti, Ta, V, AlOx, CoOx, CrOx, GaOx, HfOx, MnOx, MoOx, NbOx, NiOx, RuOx, SiCOx, SiOx, TaOx, TiOx, WOx, ZnOx, ZrOx, TaN, MoNx, WNx, TiN, VCx, MoCx, NbCx, TaCx, TiCx, or WCx, or any combination thereof. The process may also include removing a remaining portion of the inhibitor layer responsive to exposing the substrate to the removal agent which can include H2 plasma or O3.

In one aspect, a method for selective deposition on a substrate, includes a) providing the substrate in a reaction chamber, the substrate includes a first surface and a second surface, where the first surface is materially different from the second surface, where the first surface is a metal oxide, metal nitride, metal oxynitride, or a metal carbide or a combination thereof, where the second surface is a dielectric or a metal, and b) contacting the substrate with a precursor includes a hydrophobic compound to selectively deposit a passivation layer on the first surface relative to the second surface. The method may also include c) purging the reaction chamber, and performing at least one of operations b), and c), until the passivation layer is selectively deposited onto the first surface relative to the second surface to a predetermined thickness. The method may also include where the precursor includes an alkylaminosilane represented by general formula (1):

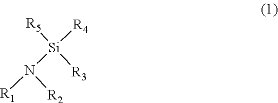

where R1 and R2 each independently comprise an H or an alkyl group, where R3 and R4 each independently comprise an H, an alkyl or an amino group of the formula NR1R2, where any two or more of R1, R2, R3, and R4 can comprise a same alkyl group, and where R5 is a hydrophobic halocarbon. The method may also include where the hydrophobic halocarbon is a fluorocarbon chain.

Other technical features may be readily apparent to one skilled in the art from the following figures, descriptions, and claims.

For the purpose of summarizing the disclosure and the advantages achieved over the prior art, certain objects and advantages of the disclosure have been described herein above. Of course, it is to be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates simplified cross-sectional schematic diagrams of semiconductor structures formed during cyclical selective deposition processes, in accordance with an example of the present technology.

FIG. 4 illustrates a selective deposition process, in accordance with an example of the present technology.

### DETAILED DESCRIPTION

The description of exemplary embodiments of methods, layers, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

In this disclosure, “gas” can include material that is a gas at normal temperature and pressure (NTP), a vaporized solid and/or a vaporized liquid, and can be constituted by a single gas or a mixture of gases, depending on the context. Reactants and precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction chamber, and can include a seal gas.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity.

The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. A reactant may also be a molecule that binds, such as chemisorbs, on the surface of a substrate without undergoing further chemical reactions at the surface with additional precursors and/or reactants. A reactant on a substrate surface may be modified by, for example, thermal or a plasma treatment.

In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a solution or a gas in standard conditions.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

A substrate according to various embodiments of the current disclosure comprises a first surface and a second surface. The first surface and the second surface have different material properties, allowing for the selective deposition of a passivation material on the first surface and optionally an organic polymer (e.g., an inhibitor) on the second surface. In some embodiments, the first surface and the second surface are adjacent to each other. In some embodiments, the first surface and the second surface are on the same face of a silicon wafer.

Alternatively or additionally, embodiments of the current disclosure comprise a first, second, and third surface. The first, second and third surfaces have different material properties, allowing for the selective deposition of a first passivation material on the first surface, a second passivation material on the second surface and optionally an inhibitor on the third surface. In some embodiments, the first, second and third surfaces are adjacent to each other. In some embodiments, the first, second and third surfaces are on the same face of a silicon wafer.

In some embodiments, the substrate may be pretreated or cleaned prior to or at the beginning of the selective deposition process according to the current disclosure. In some embodiments, the substrate may be subjected to a plasma cleaning process prior to or at the beginning of the selective deposition process. In some embodiments, a plasma cleaning process may include ion bombardment, exposure to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

The method of depositing one or more passivation layers and/or an inhibitor material according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices, such as a semiconductor processing assembly. The semiconductor processing assembly may comprise one or more multi-station processing chambers. The reaction chamber may be part of a cluster tool in which different processes are performed to form an integrated circuit. Various phases of the methods according to the current disclosure, such as methods of depositing a first passivation layer, a second passivation layer, an organic polymer, or methods of depositing a metal, metallic and/or dielectric material, can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be a single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber of the current disclosure can form part of an atomic layer deposition (ALD) assembly. The reaction chamber can form part of a chemical vapor deposition (CVD) assembly. The processing assembly may be an ALD or a CVD processing assembly. In some parts of the deposition process flow, molecular layer deposition (MLD) may be employed. In some embodiments, the method is performed in a single reaction chamber of a cluster tool, but other, preceding or subsequent, manufacturing steps of the structure or device are performed in additional reaction chambers of the same cluster tool. Optionally, a semiconductor processing assembly including the reaction chamber can be provided with a heater to activate the reactions by elevating the temperature of one or more of the substrate and/or the reactants and/or precursors.

### Cyclic Vapor Deposition

In some methods according to the current disclosure, particularly those of depositing an organic polymer, and dielectric material, cyclic vapor deposition methods may be used. Cyclic deposition in the current disclosure refers to vapor deposition processes in which deposition cycles, typically a plurality of consecutive deposition cycles, are conducted in a process chamber.

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, such as a dielectric material, whereas in MLD, the precursors may be fully organic molecules, such as when an organic polymer is deposited.

In some embodiments, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction chamber or substrate, or in partially or completely separated pulses. However, CVD may be performed with a single precursor, or two or more precursors that do not react with each other. A single precursor may decompose into reactive components that are deposited on the substrate surface. The decomposition may be brought about by plasma or thermal means, for example. The substrate and/or reaction chamber can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. The process may comprise one or more cyclic phases. In some embodiments, the process comprises one or more acyclic (i.e. continuous) phases. An example of a continuous phase could be a pre-treatment with a single reactant. In some embodiments, the deposition process comprises the continuous flow of at least one precursor. In some embodiments, one or more of the precursors are provided in the reaction chamber continuously.

According to some aspects of the present disclosure, selective deposition can be used to deposit a material on a first surface relative to a second surface. The two surfaces can have different material properties. According to some aspects of the present disclosure, selective deposition can be used to deposit a material on a first surface relative to a second and third surface. The three surfaces can have different material properties.

In some examples an organic material such as a polyamide or polyimide is selectively deposited on a first conductive (e.g., metal or metallic) surface of a substrate relative to a different surface (e.g. a second and/or third surface) of the substrate. In some examples, the polyamide or polyimide is selectively deposited on a first conductive (e.g., metal or metallic) surface and the different surface(s) may comprise OH groups, such as a silicon oxide-based surface. In some examples the different surface(s) may additionally comprise H terminations, such as an HF dipped Si or HF dipped Ge surface. In some examples, the polyamide or polyimide is selectively deposited on a first conductive (e.g., metal or metallic) surface and the different surface(s) comprise a passivation material (e.g., first passivation layer 324 or second passivation layer 330 discussed in more detail below). In some examples, the dielectrics have different compositions (e.g., silicon, silicon nitride, carbon, silicon oxide, silicon oxynitride, germanium oxide). In other such examples, the dielectrics can have the same basic composition (e.g., silicon oxide-based layers) but different material properties due to the manner of formation (e.g., thermal oxides, native oxides, deposited oxides). In some examples vapor deposition methods are used. In some examples cyclical vapor deposition is used, for example, cyclical CVD or atomic layer deposition (ALD) processes are used. After selective deposition of the organic material is completed, further processing can be carried out to form the desired structures.

For examples in which one surface comprises a metal whereas one or more other surfaces do not, unless otherwise indicated, if a surface is referred to as a metal surface herein, it may be a metal surface or a metallic surface. In some examples the metal or metallic surface may comprise metal, metal oxides, and/or mixtures thereof. In some examples the metal or metallic surface may comprise surface oxidation. In some examples the metal or metallic material of the metal or metallic surface is electrically conductive with or without surface oxidation. In some examples metal or a metallic surface comprises one or more transition metals. In some examples the metal or metallic surface comprises one or more of aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof. In some examples a metallic surface comprises titanium nitride. In some examples the metal or metallic surface comprises one or more noble metals, such as Ru. In some examples the metal or metallic surface comprises a conductive metal oxide, nitride, carbide, boride, or combination thereof. For example, the metal or metallic surface may comprise one or more of RuOₓ, NbCₓ, NbBₓ, NiOₓ, CoOₓ, NbOₓ, WNCₓ, TaN, MoNₓ, WNₓ, AlOₓ, and/or TiN.

In some examples the metal or metallic surface may comprise Zn, Fe, Mn, or Mo. In some examples the metal or metallic surface may be any surface that can accept or coordinate with the first or second precursor utilized in a selective deposition process as described herein.

In some examples an organic material is selectively deposited on a metal oxide surface relative to other surfaces. A metal oxide surface may be, for example a WOₓ, HfOₓ, TiOₓ, AlOₓ or ZrOₓ, surface. In some examples a metal oxide surface is an oxidized surface of a metallic material. In some examples a metal oxide surface is created by oxidizing at least the surface of a metallic material using an oxygen compound, such as compounds comprising O₃, H₂O, H₂O₂, O₂, oxygen atoms, plasma or radicals or mixtures thereof. In some examples a metal oxide surface is a native oxide formed on a metallic material.

In some examples an organic material is selectively deposited on a metal or metallic surface of a substrate relative to a dielectric surface of the substrate. In some examples the organic material that is selectively deposited is a polyamide, polyimide, or other polymeric material. The term dielectric is used in the description herein for the sake of simplicity in distinguishing from the other surface, namely the metal or metallic surface. It will be understood by the skilled artisan that not all non-conducting surfaces are dielectric surfaces. For example, the metal or metallic surface may comprise an oxidized metal surface that is electrically non-conducting or has a very high resistivity. Selective deposition processes taught herein can deposit on such non-conductive metallic surfaces with minimal deposition on adjacent dielectric surfaces.

In some examples an organic material is selectively deposited on a metal oxide surface of a substrate relative to an SiO₂ surface. In some examples the metal oxide surface may be, for example a WOₓ, HfOₓ, TiOₓ, AlOₓ or ZrOₓ surface. In some examples the organic material is deposited on a dielectric surface relative to a SiO₂ surface. In some examples the SiO₂ surface may be, for example, a native oxide, a thermal oxide or a chemical oxide.

In some examples a substrate is provided comprising a metal or metallic surface, a metal oxide surface and a dielectric surface. In some examples the dielectric surface may be a SiO₂ based surface. In some examples the dielectric surface may comprise Si—O bonds. In some examples the dielectric surface may comprise a SiO₂ based low-k material. In some examples the dielectric surface may comprise more than about 30%, or more than about 50% of SiO₂. In some examples the dielectric surface may comprise GeO₂.

In some examples the substrate may be pretreated or cleaned prior to or at the beginning of the selective deposition process. In some examples the substrate may be subjected to a plasma cleaning process prior to or at the beginning of the selective deposition process. In some examples a plasma cleaning process may include ion bombardment, exposure to plasma, radicals, excited species, and/or atomic species prior to or at the beginning of the selective deposition process. In some examples the substrate surface may be exposed to hydrogen plasma, radicals, or atomic species prior to or at the beginning of the selective deposition process. In some examples a pretreatment or cleaning process may be carried out in the same reaction chamber as a selective deposition process, however in some examples a pretreatment or cleaning process may be carried out in a separate reaction chamber.

The term “about” is employed herein to mean within standard measurement accuracy.

Selective deposition using the methods described herein can advantageously be achieved with treatment such as passivation of a surface to block deposition thereon and/or with treatment of a surface (whether metallic or a different dielectric surface) to catalyze deposition. In some examples, a passivation layer (e.g., a self-assembled monolayer (SAM)) and/or an inhibitor layer, may be deposited on various surfaces of the substrate which may prevent the respective top surface of the substrate from being exposed to deposition processes described herein. Thus, in some examples selectivity is achieved by use of blocking or catalyzing agents, where passivated or inhibited surfaces are not directly exposed to deposition reactants.

Vapor phase deposition techniques can be applied to organic films and polymers such as polyimide films, polyamide films, polyurea films, polyurethane films, polythiophene films, and more. CVD of polymer films can produce greater thickness control, mechanical flexibility, conformal coverage, and biocompatibility as compared to the application of liquid precursor. Sequential deposition processing of polymers can produce high growth rates in small research scale reactors. Similar to CVD, sequential deposition processes can produce greater thickness control, mechanical flexibility, and conformality. The terms “sequential deposition” and “cyclical deposition” are employed herein to apply to processes in which the substrate is alternately or sequentially exposed to different precursors, regardless of whether the reaction mechanisms resemble ALD, CVD, MLD or hybrids thereof.

In some examples the processes described herein may be batch processes, that is, the processes may be carried out on two or more substrates at the same time. In some examples the processes described herein may be carried out on two or more, five or more, 10 or more, 25 or more, 50 or more, or 100 or more substrates at the same time. In some examples the substrate may comprise wafers, for example, semiconductor or silicon wafers. In some examples the substrates may have diameters of 100 mm or more, 200 mm or more, or 300 mm or more. In some instances substrates having diameters of 450 mm or more may be desirable.

### Selectivity

Selectivity can be given as a percentage calculated by [(deposition on surface A)−(deposition on surface B)]/(deposition on surface A), where surface A and surface B are comprised of different materials. Deposition can be measured in any of a variety of ways. In some examples deposition may be given as the measured thickness of the deposited material. In some examples deposition may be given as the measured amount of material deposited.

In some examples selectivity is greater than about 10%, greater than about 50%, greater than about 75%, greater than about 85%, greater than about 90%, greater than about 93%, greater than about 95%, greater than about 98%, greater than about 99% or even greater than about 99.5%. In examples described herein, the selectivity can change over the duration or thickness of a deposition.

In some examples deposition only occurs on surface A and does not occur on surface B. In some examples deposition on the surface A of the substrate relative to surface B of the substrate is at least about 80% selective, which may be selective enough for some particular applications. In some examples the deposition on surface A of the substrate relative to surface B of the substrate is at least about 50% selective, which may be selective enough for some particular applications. In some examples the deposition on surface A of the substrate relative to surface B of the substrate is at least about 10% selective, which may be selective enough for some particular applications. In some examples deposition on the first surface of the substrate relative to the second surface of the substrate is at least about 80% selective, which may be selective enough for some particular applications. In some examples the deposition on the first surface of the substrate relative to the second surface of the substrate is at least about 50% selective, which may be selective enough for some particular applications. In some examples the deposition on the first surface of the substrate relative to the second surface of the substrate is at least about 10% selective, which may be selective enough for some particular applications.

In some examples the organic film deposited on the first surface of the substrate may have a thickness less than about 50 nm, less than about 20 nm, less than about 10 nm, less than about 5 nm, less than about 3 nm, less than about 2 nm, or less than about 1 nm, while a ratio of material deposited on the first surface of the substrate relative to the second surface of the substrate may be greater than or equal to about 2:1, greater than or equal to about 20:1, greater than or equal to about 15:1, greater than or equal to about 10:1, greater than or equal to about 5:1, greater than or equal to about 3:1, or greater than or equal to about 2:1.

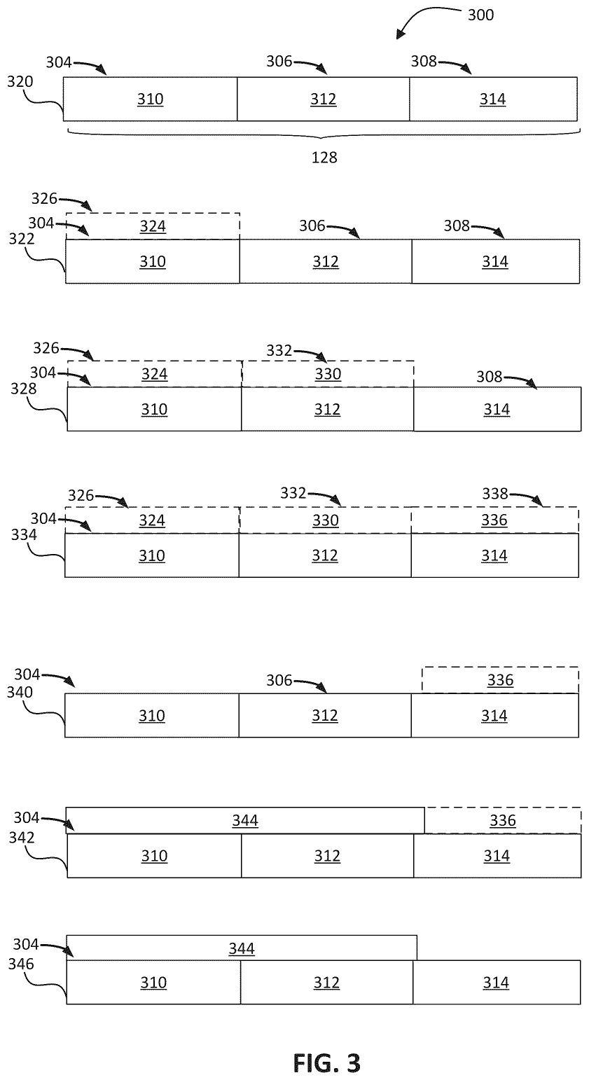

In some examples a substrate may comprise more than two materially different surfaces (e.g., a first surface 304, a second surface 306, and a third surface 308, as illustrated in FIG. 3). In such an example, deposition may occur at different selectivity levels depending upon which surfaces are compared. For example, selectivity may be 50% on first surface 304 with respect to second surface 306, and 80% on third surface 308 with respect to second surface 306. Likewise, ratios of material deposited may be different depending upon which surfaces are compared. For example, a ratio of material deposited on the first surface 304 relative to the second surface 306 may be greater than or equal to about 2:1 while a ratio of material deposited on the third surface 308 relative to the second surface 306 may be greater than or equal to about 20:1.

In some examples the selectivity of the selective deposition processes described herein may depend on the materials which comprise the first, second and third surface of the substrate. Selectivity of a deposition material may be described as a percentage or ratio of the deposition on a first surface vs a second surface even where there are multiple exposed surface materials on a single substrate.

In some examples for deposition of a metal inhibitor, where the first surface comprises W and the second surface comprises a low k silicon dioxide surface the selectivity may be greater than about 8:1 or greater than about 15:1 of the inhibitor on W to the inhibitor on the low k material. In some examples where the first surface comprises a metal or metal oxide and the second surface comprises a natural or chemical silicon dioxide surface the selectivity may be greater than about 5:1 or greater than about 10:1. In some examples where the first surface comprises a chemical or natural silicon dioxide surface and the second surface comprises a thermal silicon dioxide surface the selectivity may be greater than about 5:1 or greater than about 10:1.

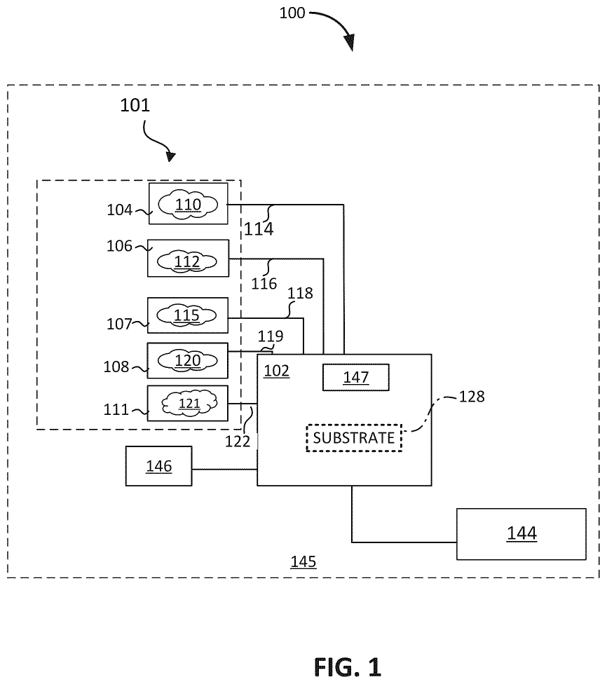

FIG. 1 illustrates a deposition assembly 100 according to the current disclosure in a schematic manner. Deposition assembly 100 can be used to perform a method as described herein and/or to selectively deposit organic material as described herein. In yet another aspect, semiconductor processing assembly 100 may be configured for selectively depositing passivation and/or inhibitor material on a first, second and/or third surface of a substrate 128.

In the illustrated example, deposition assembly 100 includes one or more reaction chambers 102, a precursor injector system 101, a first precursor vessel 104, a second precursor vessel 106, a third precursor vessel 107, a fourth precursor vessel 108, removal agent vessel 111, an exhaust source 144, a remote plasma source 146, a direct plasma source 147 and a controller 145. The deposition assembly 100 may comprise one or more additional gas sources (not shown), such as an inert gas source, a carrier gas source and/or a purge gas source. Reaction chamber 102 can include any suitable reaction chamber, such as an ALD or CVD reaction chamber as described herein.

The first precursor vessel 104 can include a vessel and one or more first precursors 110 as described herein—alone or mixed with one or more carrier (e.g., inert) gases. A second precursor vessel 106 can include a vessel and one or more second precursors 112 as described herein—alone or mixed with one or more carrier gases. A third precursor vessel 107 can include a vessel and one or more inhibitor precursors 115 as described herein—alone or mixed with one or more carrier gases. A fourth precursor vessel 108 can include a vessel and one or more inhibitor precursors 120 as described herein—alone or mixed with one or more carrier gases. A removal agent vessel 111 can include a vessel and one or more removal agents 121 as described herein—alone or mixed with one or more carrier gases. Although illustrated with four source vessels 104, 106, 107, 108 and 111 a deposition assembly 100 can include any suitable number of source vessels. Source vessels 104, 106, 107, 108 and 111 can be coupled to reaction chamber 102 via respective lines 114, 116, 118, 119 and 122, which can each include flow controllers, valves, heaters, and the like. In some examples, the first precursor 110 may be stored in the first precursor vessel 104, the second precursor 112 may be stored in the second precursor vessel 106, the first inhibitor precursor 115 may be stored in the third precursor vessel 107, second inhibitor precursor 120 may be stored in the second inhibitor precursor vessel 108 and removal agent 121 may be stored in the removal agent vessel 111. Source vessels 104, 106, 107, 108 and 111 may be heated.

Exhaust source 144 can include one or more vacuum pumps. Controller 145 includes electronic circuitry and software to selectively operate valves, manifolds, heaters, pumps and other components included in the deposition assembly 100. Such circuitry and components operate to introduce precursors, reactants and purge gases from the respective sources.

Controller 145 can control timing of gas pulse sequences, temperature of the substrate and/or reaction chamber 102, pressure within the reaction chamber 102, and various other operations to provide proper operation of the deposition assembly 100. Controller 145 can include control software to electrically or pneumatically control valves to control flow of precursors, reactants and purge gases into and out of the reaction chamber 102. Controller 145 can include modules such as a software or hardware component, which performs certain tasks. A module may be configured to reside on the addressable storage medium of the control system and be configured to execute one or more processes.

Other configurations of deposition assembly 100 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 102. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 100, substrates, such as semiconductor wafer (e.g., substrate 128), are transferred from, e.g., a substrate handling system to reaction chamber 102. Once substrate(s) are transferred to reaction chamber 102, one or more gases from gas sources, such as precursors, reactants, carrier gases, and/or purge gases, are introduced into reaction chamber 102.

In an example, the first precursor 110 may comprise an alkylaminosilane material for depositing a passivation layer as described in greater detail herein. In an example, the second precursor 112 may comprise a hydrophobic material as described in greater detail herein.

In an example, the first inhibitor precursor 115 may comprise an amine (e.g., diamine, triamine, tetraamine and/or cyclic compound comprising at least two primary amine groups), as described in greater detail herein. In an example, second inhibitor precursor 120, may comprise an anhydride, such as furan-2,5-dione (maleic acid anhydride), dianhydride, (e.g., pyromellitic dianhydride (PMDA)) and/or a dianhydride comprising at least one thioanhydride group (e.g., 1,2,4,5-tetrathio-cyclic 1,2:4,5-bis(anhydrosulfide) 1,2,4,5-benzenetetracarboxylic acid (pyromellitic dithioanhydride (PMDTA))) as described in greater detail herein.

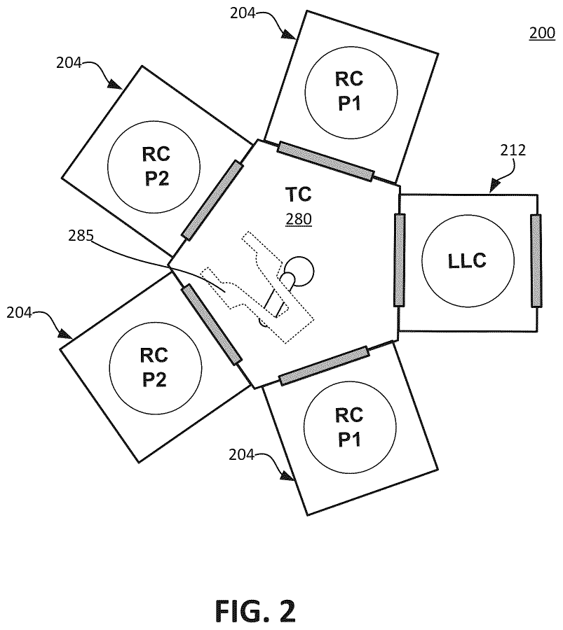

In some examples, a reactor system (e.g., reactor system 100) can comprise multiple reaction chambers. For example, in reactor system 200, shown in FIG. 2, a number of reaction chambers 204 (each of which can be an example of any of reaction chamber 102 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 128 can be disposed in different chambers for different steps of a semiconductor manufacturing process (e.g., surface clean, passivation, inhibiting, film removal, etching, oxidizing, and/or deposition steps may each be performed in the same or different chambers).

### Selective Deposition

FIG. 3 illustrates a process 300 for selective deposition on a substrate 128, wherein operations of process 300 are depicted in cross-sectional views of substrate 128.

In an example, substrate 128 comprises a first material 310 having a first surface 304, a second material 312 having a second surface 306 and a third material 314 having third surface 308. In an example, first material 310, second material 312 and third material 314 may be different material.

In an example, first material 310 and/or first surface 304 can comprise an inorganic dielectric, such as a low-k layer (typically a silicon oxide-based layer) or a silicon surface having native oxide (also a form of silicon oxide) formed thereover, for example, first material 310 and/or first surface 304 can comprise SiCOx, SiOx, SiO2, SiC, SiOC, SiON, SiOCN, SiGe, SiN, Si, high-k material, low-k material, or the like or a combination thereof.

In some examples, the second material 312 and/or second surface 306 can comprise or be defined by a metal oxide, a metal nitride, a metal oxynitride, a metal oxycarbide, or a combination thereof. In some examples, second material 312 may comprise AlOx, CoOx, CrOx, GaOx, HfOx, MnOx, MoOx, NbOx, NiOx, RuOx, SiCOx, SiOx, TaOx, TiOx, WOx, ZnOx, TiN, TaN, MoN, AlN, WN, TaON, SiCOx, SiOx, SiO2, SiC, SiOC, SiON, SiOCN, SiGe, SiN or ZrOx, the like, or a combination thereof.

In some examples, the third material 314 and/or third surface 308 can comprise or be defined by a metallic material, elemental metal, a metallic surface, or a combination thereof. In some examples, second surface 308 may comprise aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or the like, or a combination thereof.

The following description of process 300 is with reference to FIGS. 1 to 3. In an example, process 300 starts at operation 320 wherein a substrate 128 having a first surface 304, a second surface 306 and a third surface 308 is supported in a reaction chamber 102 (see FIG. 1). In some examples, first material 310 and second material 312, and third material 314 of substrate 128 may be materially different thus exposed first surface 304, second surface 306 and third surface 308 may be materially different.

Process 300 may continue to operation 322 where selective deposition of a first passivation layer 324 over first surface 304 may be performed. Passivation layer 324 having fourth surface 326 may be formed selectively on first surface 304 relative to second surface 306 and third surface 308.

In an example, selectively depositing the first passivation layer comprises contacting the substrate 128 with a first precursor (e.g., first precursor 110) comprising an alkylaminosilane. In an example, the first precursor 110 may comprise allyltrimethylsilane (TMS-A), 1,1,1-Trimethoxy-N,N-dimethylsilanamine, chlorotrimethylsilane (TMS-Cl), N-(trimethylsilyl)imidazole (TMS-Im), octadecyltrichlorosilane (ODTCS), hexamethyldisilazane (HMDS), N-(trimethylsilyl)dimethylamine (TMSDMA), 1,1,1-Trimethoxy-N,N-dimethylsilanamine, or trimethylchlorosilane, or a combination thereof.

In an example, first precursor 110 may be provided to the reaction chamber holding the substrate 128 to contact substrate 128 with a single pulse or in a sequence of multiple pulses. In some embodiments the first precursor 110 is provided in a single long pulse or in multiple shorter pulses. The pulses may be provided sequentially. In some embodiments the first precursor 110 is provided in 1 to 1000 pulses of from about 0.01 to about 600 seconds, or any appropriate number of pulses of any appropriate duration. In between pulses, the first precursor 110 may be removed from the reaction space. For example, the reaction chamber may be evacuated and/or purged with an inert gas. The purge may be, for example for about 0.01 to 600 seconds, or any appropriate pulse period.

In some embodiments, the temperature of the passivation process may be, for example, from about 25° C. to 500° C., or about 100° C. to about 300° C., or any appropriate temperature. The pressure during the passivation process may be, for example, from about 0.01 to about 760 Torr, or in some embodiments from about 1 to 10 Torr or about 0.1 to about 10 Torr.

Process 300 may continue to operation 328 where selective deposition of a second passivation layer 330 over second surface 306 may be performed. Second passivation layer 330 having fifth surface 332 may be formed selectively on second surface 306 relative to fourth surface 326 and third surface 308. Second passivation layer 330 may comprise a hydrophobic alkylsilane capable of bonding to hydroxyl groups present on surface 306.

In an example, second passivation layer 330 may comprise an alkylaminosilane.

In an example, second passivation layer 330 may comprise an alkylaminosilane comprising a hydrophobic group that is unhalogenated or partially halogenated or fully halogenated.

In an example, second passivation layer 330 may comprise an alkylaminosilane comprising a hydrophobic group that is partially halogenated or fully halogenated with one or more of fluorine, chlorine, bromine, or iodine.

In some examples, the alkylaminosilane may comprise a hydrophobic group that is partially halogenated or fully halogenated with fluorine.

In an example, selectively depositing the second passivation layer 330 comprises contacting the substrate 128 with a second precursor (e.g., second precursor 112) comprising a non-chlorinated hydrophobic alkylsilane. The non-chlorinated hydrophobic alkylsilane may be an alkylaminosilane, a bis-alkylaminosilane, or a tris-alkylaminosilane.

In some examples, the alkylaminosilane may comprise a hydrophobic group comprising an alkyl and/or an aryl group.

In some examples, the alkylaminosilane may comprise a hydrophobic group comprising a hydrophobic halocarbon comprising one or more of CH2, CHX and/or CX2 units, where X is independently selected from fluorine, chlorine, bromine, or iodine.

In some examples, the alkylaminosilane may comprise a hydrophobic group comprising a non-chlorinated hydrophobic halocarbon comprising one or more of CH2, CHX and/or CX2 units, where X is independently selected from fluorine, bromine, or iodine.

In some examples, the alkylaminosilane may comprise a hydrophobic group comprising a hydrophobic fluorocarbon chain comprising CH2, CHF and/or CF2 units.

In some examples, the hydrophobic group may comprise an alkyl and/or an aryl group having 100 or fewer carbon atoms, or 75 or fewer carbon atoms, or 50 or fewer carbon atoms, or 25 or fewer carbon atoms, or any appropriate number of carbon atoms.

In some examples, the second precursor 112 may be an alkylaminosilane comprising a structure represented by the general formula (1):

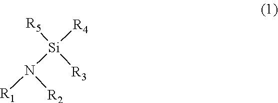

where R1 and R2 each independently comprise an H or an alkyl group; where R3 and R4 each independently comprise an H, an alkyl or an amino group of the formula NR1R2; wherein any two or more of R1, R2, R3, and R4 can comprise the same alkyl group; and wherein R5 is a hydrophobic halocarbon.

In some examples, R5 is a hydrophobic group comprising an alkyl and/or an aryl group.

In some examples, R5 is a hydrophobic group comprising a hydrophobic halocarbon comprising one or more of CH2, CHX and/or CX2 units, where X is independently selected from fluorine, chlorine, bromine, or iodine.

In some examples, R5 is a hydrophobic group comprising a non-chlorinated hydrophobic halocarbon comprising one or more of CH2, CHX and/or CX2 units, where X is independently selected from fluorine, bromine, or iodine.

In some examples, R5 is a hydrophobic group comprising a hydrophobic fluorocarbon chain comprising CH2, CHF and/or CF2 units.

In some examples, R5 comprises a C1-C100 chain comprising, units independently selected from: unhalogenated C, CX, CX2, or CX3, where X is independently selected from fluorine, chlorine, bromine, or iodine.

In some examples, R5 comprises a C1-C100 chain comprising, units independently selected from: unfluorinated C, CF, CF2, or CF3.

In some examples, R1, R2, R3 and R4 can each independently comprise an alkyl selected from the group consisting of: methyl, ethyl, n-propyl, isopropyl, n-butyl, i-butyl, t-butyl, or s-butyl.

In some examples, the alkylaminosilane may be tridecafluoro-1,1,2,2-tetrahydrooctylmethyl-bis(dimethylamino)silane.

In an example, second precursor 112 may be provided to the reaction chamber holding the substrate 128 to contact substrate 128 with a single pulse or in a sequence of multiple pulses. In some embodiments the second precursor 112 is provided in a single long pulse or in multiple shorter pulses. The pulses may be provided sequentially. In some embodiments the first precursor 112 is provided in 1 to 1000 pulses of from about 0.01 to about 600 seconds, or any appropriate number of pulses of any appropriate duration (e.g., longer periods of time depending on temperature). In between pulses, the second precursor 112 may be removed from the reaction space. For example, the reaction chamber may be evacuated and/or purged with an inert gas. The purge may be, for example for about 0.01 to 600 seconds or more.

In some embodiments, the temperature of the passivation process may be, for example, from about 25° C. to 500° C., or about 100 to about 300° C. The pressure during the passivation process may be, for example, from about 0.01 to about 760 Torr, or in some embodiments from about 1 to 10 Torr or about 0.1 to about 10 Torr.

In an example, process 300 may move to operation 334, where selective deposition of an inhibitor layer 336 on third surface 308 may be performed. Inhibitor layer 336 having surface 338 may be formed selectively on third surface 308 relative to fourth surface 326 and fifth surface 332. Inhibitor layer 336 may comprise a polyamide, polyimide, dimer, trimer, polyurethane, polythiourea, polyester, polyimine, other polymer capable of preferentially forming on metal surface 308.

In an example, selectively depositing the inhibitor layer 336 comprises contacting the substrate 128 with a first inhibitor precursor (e.g., first inhibitor precursor 115) comprising an amine such as a diamine (e.g., 1,6-diamnohexane (DAH)), a triamine (e.g., tris(aminoethyl)methylsilane), a tetraamine (e.g., 2,2-bis(aminomethyl)-1,3-propanediamine) and/or a cyclic compound comprising at least two primary amine groups and contacting the substrate with a second inhibitor precursor (e.g., second inhibitor precursor 120) comprising an anhydride, such as furan-2,5-dione (maleic acid anhydride), a dianhydride (e.g., pyromellitic dianhydride (PMDA) and/or pyromellitic dithioanhydride (PMDTA)), or any other species with two reactive groups which will react with the first inhibitor precursor. Such first inhibitor precursors and second inhibitor precursors are disclosed in U.S. Patent Application Ser. No. 63/546,475, filed Oct. 30, 2023, the entire disclosure of which is incorporated herein by reference for all purposes. Additional or alternative example processes for selectively depositing such an inhibitor layer 336 comprising polyamide or polyimide by vapor deposition techniques are disclosed in U.S. patent Ser. No. 10,373,820 issued Aug. 6, 2019, the entire disclosure of which is incorporated herein by reference for all purposes.

In an example, process 300 may move to operation 340, where passivation layer 324, passivation layer 330, and/or a portion of inhibitor layer 336 may be removed. In an example, passivation layer 324 and passivation layer 330 may be removed by heat treatment at temperatures lower than those that would remove a polymer layer comprising inhibitor layer 336.

In another example, passivation layer 324 and passivation layer 330 may be completely or almost completely removed by exposing the substrate 128 to a removal agent (e.g., removal agent 121). In certain examples the removal agent may be a plasma or O3. An advantage of using O3 may be that removal of the passivation layers and inhibitor layer may be done the same chamber as previous deposition processes.

More specifically, substrate 128 is shown at operation 340 after removal of the passivation layer 324 from first surface 304, removal of passivation layer 330 from second surface 306, and a portion of inhibitor layer 336 from third surface 308. In some examples, an etch process may be employed to remove passivation layer 324, passivation layer 330, and/or a portion of inhibitor layer 336 comprising exposing the substrate to a plasma. In some examples, the plasma may comprise oxygen atoms, oxygen radicals, oxygen plasma, or combinations thereof. In some examples, the plasma may comprise hydrogen atoms, hydrogen radicals, hydrogen plasma, or combinations thereof. In some examples, the plasma may comprise NH3 molecules, NH3 plasma, or combinations thereof. In some examples, the plasma may also comprise inert gas species, for example Ar, N2 or He species. In some examples the plasma may consist essentially of inert gas species. In some instances, the plasma may comprise other species, for example nitrogen atoms, nitrogen radicals, nitrogen plasma, or combinations thereof.

In some examples, the etch process may comprise exposing the substrate to an etchant comprising oxygen, for example O₃. In some examples, the substrate may be exposed to an etchant at a temperature of between about 25° C. and about 500° C., preferably between about 100° C. and about 400° C. In some examples, the etchant may be supplied in one continuous pulse or may be supplied in multiple shorter pulses.

As noted above, in some examples, O₃ (e.g. O₃/N₂) can be used in the etch process for removal of passivation layer 324, passivation layer 330, and/or a portion of inhibitor layer 336. In some examples, the etch process may be performed at a substrate temperature of about 25° C. to about 500° C.

In some examples, the etch process may be performed at a rate of about 0.001 nm/min to about 500.0 nm/min. In some examples, the etch process may be performed at a rate of about 0.1 nm/min to about 5.0 nm/min. In some examples for single wafer or small batch (e.g., 5 wafers or less) processing, a low O₃ concentration etch process may be used, wherein the low O₃ concentration etch process is performed at 0.01 Torr to 760 Torr, more particularly about 0.1 Torr to 100 Torr (e.g., 2 Torr). Etchant pulsing can be between 0.001 sec and 1800 seconds, particularly between 1 sec and 50 sec. O₃ flow can range from 0.001 slm to 50 slm, more particularly from 0.1 slm to 1 slm. Inert (e.g., N₂) carrier gas flow of can range from 0.001 slm to 50 slm, more particularly from 0.1 slm to 1 slm.

Process 300 may proceed to operation 342, where material layer 344 is deposited on first surface 304, second surface 306 or (if exposed) a portion of third surface 308, or a combination thereof. Most of surface 308 may remain covered by inhibitor layer 336 and thus material layer 344 will not cover unexposed areas of third surface 308. Material layer 344 may comprise the same material as material 310 or may be any of a variety of different materials. For example, material layer 344 may be a different metal oxide (e.g., any metal oxide including but not limited to AlOx, CoOx, CrOx, GaOx, HfOx, MnOx, MoOx, NbOx, NiOx, RuOx, SiCOx, SiOx, TaOx, TiOx, WOx, ZnOx, or ZrOx, or any combination thereof), metal nitrides (e.g., a metal nitride including but not limited to TaN, MoNx, WNx, or TiN or any combination thereof), metals (e.g., including but not limited to Al, Cu, W, Co, Nb, Mo, Ru, Ti, Ta or V or any combination thereof), metal carbides (e.g., metal carbides including but not limited to VCx, MoCx, NbCx, TaCx, TiCx, or WCx or any combination thereof), silicon oxynitrides or silicon oxycarbides, or any combination thereof or any other appropriate material.

In an example, process 300 may move to operation 346, where inhibitor layer 336 may be completely removed. In an example, a remaining portion of the inhibitor layer 336 may be completely or almost completely removed by exposing the substrate 128 to a removal agent (e.g., removal agent 121) at an appropriate temperature and pressure. In certain examples the removal agent may be an H2 plasma or O3 or the same or similar methods described above with respect to operation 340 to remove passivation layers. Again, an advantage of using O3 to remove inhibitor layer may be that removal of the first and second passivation layers and inhibitor layer may be done in the same chamber as previous deposition processes. Layer 336 requires additional time and power for removal.

In particular embodiments, surfaces 304, 306, and 308 may comprise various topologies within a device including but not limited to 2D or 3D structures, within a gap feature, where surfaces 304, 306, and 308 are parallel, and/or at various angles to one another and/or adjacent to one another and/or in repeating patterns, or the like or combinations thereof.

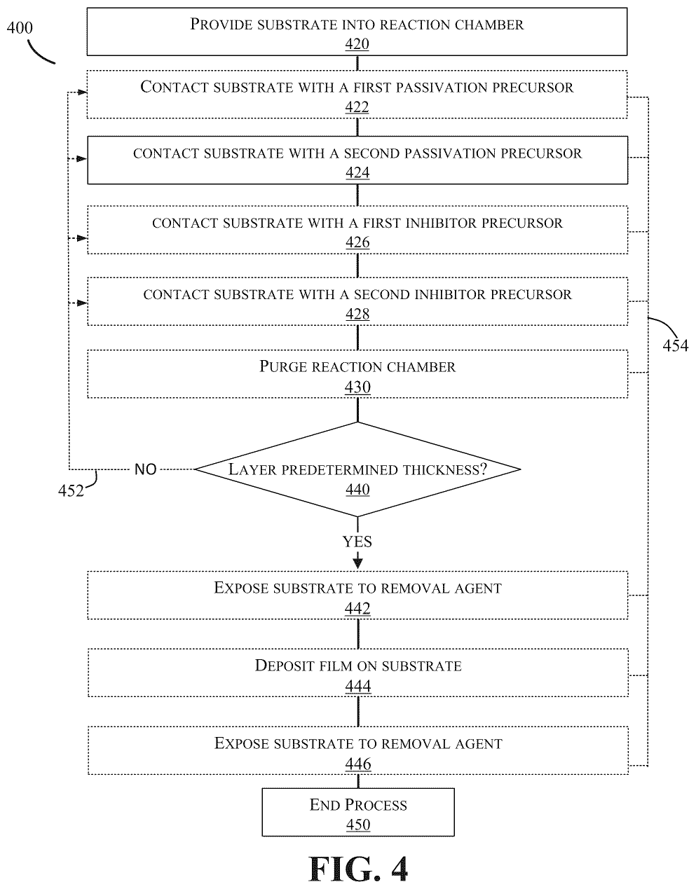

FIG. 4 illustrates an example process 400 for selective deposition of a metal on a substrate according to embodiments of the current disclosure. In an example, process 400 may comprise providing a substrate (e.g., substrate 128 shown in FIG. 3) in a reaction chamber (e.g., reaction chamber 102 shown in FIG. 1), wherein the substrate comprises a first surface (e.g., first surface 304 shown in FIG. 3), a second surface (e.g., second surface 306 shown in FIG. 3) and/or a third surface (e.g., third surface 308 shown in FIG. 3), or a combination thereof. The first surface, the second surface and/or the third surface may comprise materially different substances. The selective deposition process 400 may further comprise depositing a first passivation layer (e.g., first passivation layer 324 shown in FIG. 3) having a fourth surface (e.g., fourth surface 326 shown in FIG. 3), depositing a second passivation layer (e.g., first passivation layer 330 shown in FIG. 3) having a fifth surface (e.g., fifth surface 332 shown in FIG. 3) and/or depositing an inhibitor layer (e.g., inhibitor layer 336 shown in FIG. 3) having a sixth surface (e.g., sixth surface 338 shown in FIG. 3). The fourth surface, fifth surface and sixth surface may be materially different substances. In an example, selective deposition of the first passivation layer, the second passivation layer and/or the inhibitor layer may occur in any order and claimed subject matter is not limited in this regard.

The selective deposition process 400 may further comprise removing the first passivation layer, removing the second passivation layer, and/or removing the inhibitor layer. The selective deposition process 400 may further comprise depositing a metal layer (e.g., metal layer 344 shown in FIG. 3) over the first surface, the second surface and/or the third surface, or a combination thereof. In an example, selective removal of the first passivation layer, the second passivation layer and/or the inhibitor layer may occur in any order and claimed subject matter is not limited in this regard. In an example, process 400 may begin at operation 420, where a substrate may be provided in a reaction chamber. In an example, the substrate may comprise two or more of the first surface, the second surface and/or the third surface.

Process 400 may move to operation 422, where a first precursor (e.g., first precursor 110 shown in FIG. 1) comprising an alkylaminosilane may contact the substrate to selectively deposit the first passivation layer on the first surface relative to the second surface and/or the third surface (e.g., where the first passivation layer 324 is deposited prior to the second passivation layer 330 and the inhibitor layer 336). Alternatively, the first precursor may contact the substrate to selectively deposit the first passivation layer on the first surface relative to the fifth surface of the second passivation layer and/or the third surface of the substrate (e.g., where the second passivation layer 330 is deposited prior to deposition of the first passivation layer 324 and/or the inhibitor layer 336). Alternatively, the first precursor may contact the substrate to selectively deposit the first passivation layer on the first surface relative to the fifth surface of the second passivation layer and/or the sixth surface of the inhibitor layer (e.g., where the second passivation layer 330 and the inhibitor layer 336 are deposited prior to deposition of the first passivation layer 324). For the sake of brevity, the above examples are intended to be illustrative. An exhaustive list of all possible combinations of deposition patterns of the first passivation layer on various surfaces of the substrate with respect to various other surfaces of the substrate or layers deposited thereon is not specifically recited herein and claimed subject matter is not limited in this regard.

Process 400 may move to operation 424, where a second precursor (e.g., second precursor 112 shown in FIG. 1) comprising a hydrophobic compound may contact the substrate to selectively deposit a second passivation layer on the second surface relative to the third surface of the substrate and the fourth surface of the first passivation layer (e.g., where the second passivation layer 330 is deposited subsequent to deposition of the first passivation layer 324 and prior to deposition of the inhibitor layer 336). Alternatively, the second precursor may contact the substrate to selectively deposit the second passivation layer on the second surface relative to the first surface of the substrate and the third surface of the substrate (e.g., where the second passivation layer 330 is deposited prior to deposition of the first passivation layer 324 and the inhibitor layer 336).

Alternatively, the second precursor may contact the substrate to selectively deposit the second passivation layer on the second surface relative to the fourth surface of the first passivation layer and the sixth surface of the inhibitor layer (e.g., where the second passivation layer 330 is deposited subsequent to deposition of the first passivation layer 324 and the inhibitor layer 336). For the sake of brevity, the above examples are intended to be illustrative. An exhaustive list of all possible combinations of deposition patterns of the second passivation layer on various surfaces of the substrate with respect to various other surfaces of the substrate or layers deposited thereon is not specifically recited herein and claimed subject matter is not limited in this regard.

In an example, process 400 may proceed to operations 426 and 428, where a first inhibitor precursor (e.g., first inhibitor precursor 115 shown in FIG. 1) comprising an amine may contact the substrate and a second inhibitor precursor (e.g., second inhibitor precursor 120 shown in FIG. 1) comprising a dianhydride may contact the substrate to selectively deposit an inhibitor layer on the third surface of the substrate relative to the fourth surface of the first passivation layer and the fifth surface of the second passivation layer (e.g., where the inhibitor layer 336 is deposited subsequent to deposition of the first passivation layer 324 and the second passivation layer 330). Alternatively, first inhibitor precursor and second inhibitor precursor may contact the substrate to selectively deposit the inhibitor layer on the third surface of the substrate relative to the first surface of the substrate and the fifth surface of the second passivation layer (e.g., where the inhibitor layer is deposited subsequent to deposition of the second passivation layer 330 and prior to deposition of the first passivation layer 324). Alternatively, first inhibitor precursor and second inhibitor precursor may contact the substrate to selectively deposit the inhibitor layer on the third surface of the substrate relative to the fourth surface of the first passivation layer and the second surface of the substrate (e.g., where the inhibitor layer is deposited subsequent to deposition of the first passivation layer 324 and prior to deposition of the second passivation layer 330). For the sake of brevity, the above examples are intended to be illustrative. An exhaustive list of all possible combinations of deposition patterns of the inhibitor layer on various surfaces of the substrate with respect to various other surfaces of the substrate or layers deposited thereon is not specifically recited herein and claimed subject matter is not limited in this regard.

Moreover, process 400 may be executed to deposit first passivation layer, second passivation layer and inhibitor layer. Alternatively, second passivation layer may be deposited on a surface of a substrate with either of first passivation layer 324 or inhibitor layer 336, or both first passivation layer 324 and inhibitor layer 336, as indicated with dotted lines at operation blocks 422, 426 and 428.

In an example, process 400 may proceed to operation 430 where the reaction chamber may be purged by pulsing purge gas into the reaction chamber. In an example, cyclical deposition process 400 as described herein can comprise one or more purges. As illustrated with dotted line 454, one or more purges can precede, separate, and/or follow one or more of operations 420, 422, 424, 426, and/or 428. A purge may intermittently expose the substrate to a purge gas. Suitable purge gasses include inert or substantially inert gasses. In some embodiments, the purge gas comprises one or more of N2 and/or a noble gas. Suitable noble gasses include He, Ne, Ar, Kr, and Xe.

In an example, process 400 may include performing operations 422, 424, 426, 428 or 430 or any combination thereof, in any order, any number of times until the respective first passivation layer, second passivation layer and/or inhibitor layer reach a predetermined thickness. Operations 422, 424, 426, 428 and/or 430 or any combination thereof may be performed cyclically until the predetermined thickness of each respective first passivation layer, second passivation layer and/or inhibitor layer has been achieved. This is indicated with dotted line 452.

In an example, process 400 may proceed to operation 442 where the substrate may be exposed to a removal agent to removing the first passivation layer, the second passivation layer and/or a portion of the inhibitor layer responsive to exposure to the removal agent. In an example, the removal agent may any of a variety of removal agents as discussed in greater detail hereinabove. Again, an advantage of using O3 may be that removal of the passivation layers and inhibitor layer may be done the same chamber as previous deposition processes.

In an example, process 400 may proceed to operation 444 where a layer may be deposited over the first surface and the second surface and a portion of the third surface. The layer may comprise a variety of materials as described herein above in greater detail.

In an example, process 400 may proceed to operation 446 where the substrate may be exposed to a removal agent to removing the first passivation layer, the second passivation layer and/or a portion of the inhibitor layer responsive to exposure to the removal agent. In an example, the removal agent may any of a variety of removal agents as discussed in greater detail hereinabove.

In an example, process 400 may proceed to operation 450 where the process may end.

A skilled artisan can readily determine the optimal exposure time, temperature, and power for removing the desired amount of deposited organic material from the substrate.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various processes, systems, and configurations, and other features, functions, acts, and/or properties disclosed herein, as well as any and all equivalents thereof.

1. A process for selective deposition of a metal on a substrate, comprising:
a) providing the substrate in a reaction chamber, the substrate comprising a first surface, a second surface and a third surface;
b) contacting the substrate with a first precursor comprising a first alkylaminosilane to selectively deposit a first passivation layer on the first surface;
c) contacting the substrate with a second precursor comprising a hydrophobic group to selectively deposit a second passivation layer on the second surface; and
d) contacting the substrate with a first inhibitor precursor comprising an amine and e) contacting the substrate with a second inhibitor precursor comprising a dianhydride to selectively deposit an inhibitor layer on the third surface.

2. The process of claim 1, further comprising:
f) purging the reaction chamber; and
performing at least one of operations b), c), d), e), or f) in any order, until the first passivation layer, the second passivation layer or the inhibitor layer, or a combination thereof, are deposited onto respective ones of the first surface, the second surface or the third surface, or a combination thereof.

3. The process of claim 2, further comprising:
repeating the performing the at least one of operations b), c), d), e), or f) in any order, until at least one of the first passivation layer reaches a first predetermined thickness, the second passivation layer reaches a second predetermined thickness or the inhibitor layer reaches a third predetermined thickness, or a combination thereof.

4. The process of claim 1, wherein:
the first passivation layer has a fourth surface and is deposited relative to the second surface and the third surface;
the second passivation layer has a fifth surface and is deposited relative to the third surface and the fourth surface; and
the inhibitor layer has a sixth surface and is deposited relative to the fourth surface and the fifth surface.

5. The process of claim 1, wherein the first surface comprises a dielectric surface.

6. The process of claim 5, wherein the dielectric surface is a low-k material.

7. The process of claim 1, wherein the second surface comprises a metal oxide, metal nitride, metal oxynitride, or a metal carbide or a combination thereof.

8. The process of claim 7, wherein the second surface comprises AlOx, CoOx, CrOx, GaOx, HfOx, MnOx, MoOx, NbOx, NiOx, RuOx, TaOx, TiOx, WOx, ZnOx, TiN, TaN, MoN, AlN, WN, TaON, SiCOx, SiOx, SiO2, SiC, SiOC, SiON, SiOCN, SiGe, SiN or ZrOx, or any combination thereof.

9. The process of claim 1, wherein the third surface comprises a metal.

10. The process of claim 9, wherein the metal comprises aluminum (Al), chromium (Cr), cobalt (Co), copper (Cu), gallium (Ga), indium (In), iron (Fe), manganese (Mn), molybdenum (Mo), nickel (Ni), niobium (Nb), ruthenium (Ru), tantalum (Ta), titanium (Ti), tungsten (W), vanadium (V), or zinc (Zn), or a combination thereof.

11. The process of claim 1, wherein the first alkylaminosilane is allyltrimethylsilane (TMS-A), chlorotrimethylsilane (TMS-Cl), N-(trimethylsilyl)imidazole (TMS-Im), octadecyltrichlorosilane (ODTCS), hexamethyldisilazane (HMDS), N-(trimethylsilyl)dimethylamine (TMSDMA), trimethylchlorosilane, or 1,1,1-Trimethoxy-N,N-dimethylsilanamine or a combination thereof.

12. The process of claim 1, wherein the second precursor comprises a second alkylaminosilane comprising a hydrophobic group that is partially halogenated or fully halogenated with one or more of fluorine, chlorine, bromine, or iodine.

13. The process of claim 1, wherein the second precursor comprises a second alkylaminosilane comprising a structure represented by general formula (1): 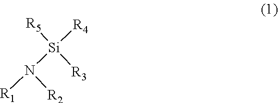
where R1 and R2 each independently comprise an H or an alkyl group; where R3 and R4 each independently comprise an H, an alkyl or an amino group of the formula NR1R2; wherein any two or more of R1, R2, R3, and R4 can comprise a same alkyl group; and wherein R5 is a hydrophobic halocarbon.

14. The process of claim 13, wherein R5 comprises an alkyl or an aryl group, or a combination thereof.

15. The process of claim 13, wherein the hydrophobic halocarbon is a carbon chain comprising one or more of CH2, CHX and CX2 units; where X is independently selected from fluorine, chlorine, bromine, or iodine.

16. The process of claim 15, wherein the hydrophobic halocarbon is non-chlorinated.

17. The process of claim 13, wherein the hydrophobic halocarbon is a fluorocarbon chain comprising CH2, CHF or CF2 units, or a combination thereof.

18. The process of claim 13, wherein R5 comprises a C1-C100 chain comprising, units independently selected from: unhalogenated C, CX, CX2, or CX3, where X is independently selected from fluorine, chlorine, bromine, or iodine.

19. The process of claim 13, wherein the second alkylaminosilane comprises dialkylaminosilane and the hydrophobic halocarbon comprises 1-100 carbon atoms.

20. The process of claim 13, wherein R1, R2, R3 and R4 each independently comprise an alkyl selected from the group consisting of: methyl, ethyl, n-propyl, isopropyl, n-butyl, i-butyl, t-butyl, or s-butyl.

21. The process of claim 1, wherein the second precursor comprises tridecafluoro-1,1,2,2-tetrahydrooctylmethyl-bis(dimethylamino)silane.

22. The process of claim 1, wherein the amine is a diamine, a triamine, a tetraamine, or a cyclic compound comprising at least two primary amines, or a combination thereof.

23. The process of claim 1, wherein the dianhydride is pyromellitic dianhydride (PMDA) or pyromellitic dithioanhydride (PMDTA).

24. The process of claim 1, further comprising:
exposing the substrate to a removal agent; and
removing the first passivation layer, the second passivation layer and a portion of the inhibitor layer responsive to exposure to the removal agent.

25. The process of claim 24, wherein the removal agent is H2 plasma or O3.

26. The process of claim 24, further comprising subsequent to the removing, depositing a film over the first surface, the second surface, or a portion of the third surface, or a combination thereof.

27. The process of claim 26, wherein the film comprises a metal, a metal nitride, a metal carbide, a silicon oxynitride or a silicon oxycarbide, or any combination thereof.

28. The process of claim 27, wherein the film comprises Al, Cu, W, Co, Nb, Mo, Ru, Ti, Ta, V, AlOx, CoOx, CrOx, GaOx, HfOx, MnOx, MoOx, NbOx, NiOx, RuOx, SiCOx, SiOx, TaOx, TiOx, WOx, ZnOx, ZrOx, TaN, MoNx, WNx, TiN, VCx, MoCx, NbCx, TaCx, TiCx, or WCx, or any combination thereof

29. The process of claim 26, further comprising removing a remaining portion of the inhibitor layer responsive to exposing the substrate to the removal agent comprising H2 plasma or O3.

30. A method for selective deposition on a substrate, comprising:
a) providing the substrate in a reaction chamber, the substrate comprising a first surface and a second surface, wherein the first surface is materially different from the second surface, wherein the first surface is a metal oxide, metal nitride, metal oxynitride, or a metal carbide or a combination thereof, wherein the second surface is a dielectric or a metal; and
b) contacting the substrate with a precursor comprising a hydrophobic compound to selectively deposit a passivation layer on the first surface relative to the second surface.

31. The method of claim 30, further comprising:
c) purging the reaction chamber; and
performing at least one of operations b), and c), until the passivation layer is selectively deposited onto the first surface relative to the second surface to a predetermined thicknesses.

32. The method of claim 31, wherein the precursor comprises an alkylaminosilane comprising a structure represented by general formula (1): 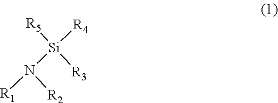
where R1 and R2 each independently comprise an H or an alkyl group; where R3 and R4 each independently comprise an H, an alkyl or an amino group of the formula NR1R2; wherein any two or more of R1, R2, R3, and R4 can comprise a same alkyl group; and wherein R5 is a hydrophobic halocarbon.

33. The method of claim 32, wherein the hydrophobic halocarbon is a fluorocarbon chain.
